(19) United States
(12) Patent Application Publication
(10) Pub. No.: US 2022/0231064 A1
(43) Pub. Date: Jul. 21, 2022

(54) IMAGE SENSOR WITH MULTIPLE COLOR FILTERS

(71) Applicant: SAMSUNG ELECTRONICS CO., LTD., Suwon-si (KR)

(72) Inventors: YOUNGWOO CHUNG, Yongin-si (KR); Sooeon Kim, Seoul (KR); Jinyoung Kim, Ulsan (KR); Hyehi Shin, Suwon-si (KR); Eungkyu Lee, Seoul (KR); Jeongrae Jo, Hwaseong-si (KR)

(21) Appl. No.: 17/648,294

(22) Filed: Jan. 18, 2022

(30) Foreign Application Priority Data
Jan. 19, 2021 (KR) 10-2021-0007370

(51) Int. Cl. H01L 27/146

(52) U.S. Cl. CPC H01L 27/14621; H01L 27/14623; H01L 27/14636; H01L 27/14627

(57) ABSTRACT

An image sensor includes a substrate that includes a plurality of photoelectric conversion devices, an insulating structure disposed on the substrate, a grid pattern structure disposed on the insulating structure, a plurality of color filters disposed on the insulating structure, and a plurality of microlenses disposed on the plurality of color filters. The grid pattern structure includes a first pattern portion and a plurality of second pattern portions spaced apart from the first pattern portion. The first pattern portion is disposed between proximate pairs of color filters among the plurality of color filters. An entire side surface of each second pattern portion of the plurality of second pattern portions is respectively surrounded by a color filter from among the first to third color filters.

### CROSS-REFERENCE TO RELATED APPLICATIONS

This application claims priority under 35 U.S.C. § 119 to Korean Patent Application No. 10-2021-0007370, filed on Jan. 19, 2021 in the Korean Intellectual Property Office, the disclosure of which is incorporated by reference herein in its entirety.

### TECHNICAL FIELD

The present disclosure relates to an image sensor, specifically to an image sensor which includes multiple color filters.

### DISCUSSION OF RELATED ART

Image sensors, which capture images and convert the images into electrical signals, may not only be used in electronic devices for general consumers such as digital cameras, mobile phone cameras, portable camcorders, or the like, but also in cameras which are installed in vehicles, security devices, robots, or the like. It is desirable to miniaturize image sensors while maintaining a high resolution of such image sensors.

### SUMMARY

Embodiments of the inventive concept provide an image sensor which has increased resolution.

According to an embodiment of the inventive concept, an image sensor includes a first chip structure that includes a first substrate, a first circuit device and a first interconnection structure disposed on the first substrate, and a first insulating layer covering the first circuit device and the first interconnection structure, and a second chip structure disposed on the first chip structure. The second chip structure includes a second substrate that includes a first surface facing the first chip structure and a second surface opposing the first surface, a second circuit device and a second interconnection structure disposed between the first surface of the second substrate and the first chip structure, a second insulating layer covering the second circuit device and the second interconnection structure, photoelectric conversion devices disposed in the second substrate, an insulating structure disposed on the second surface of the second substrate, a grid pattern structure disposed on the insulating structure, a plurality of color filters disposed on the insulating structure and the grid pattern structure, and a plurality of microlenses disposed on the color filters. The grid pattern structure includes a first pattern portion arranged in a grid shape and a plurality of second pattern portions spaced apart from the first pattern portion. An upper surface of each color filter of the plurality of color filters is disposed on a higher level than an upper surface of the grid pattern structure.

According to an embodiment of the inventive concept, an image sensor includes a substrate that includes a plurality of photoelectric conversion devices, an insulating structure disposed on the substrate, a grid pattern structure disposed on the insulating structure, a plurality of color filters disposed on the insulating structure, and a plurality of microlenses disposed on the plurality of color filters. The grid pattern structure includes a first pattern portion and a plurality of second pattern portions spaced apart from the first pattern portion. The plurality of color filters includes a first color filter corresponding to a first color, a second color filter corresponding to a second color that is different from the first color, and a third color filter corresponding to a third color that is different from the first and second colors. The first pattern portion is disposed between proximate pairs of color filters among the plurality of color filters. An entire side surface of each second pattern portion of the plurality of second pattern portions is respectively surrounded by a color filter from among the first to third color filters.

According to an embodiment of the inventive concept, an image sensor includes a substrate that includes a first plurality of adjacent pixel regions, a second plurality of adjacent pixel regions, and a third plurality of adjacent pixel regions, an insulating structure disposed on the substrate, a grid pattern structure disposed on the insulating structure, a plurality of color filters disposed on the insulating structure, and a plurality of microlenses disposed on the plurality of color filters. The grid pattern structure includes a first pattern portion and a plurality of second pattern portions spaced apart from the first pattern portion. The plurality of color filters includes a first color filter corresponding to a first color, a second color filter corresponding to a second color that is different from the first color, and a third color filter corresponding to a third color that is different from the first and second colors. The first pattern portion is disposed between proximate pairs of color filters among the plurality of color filters. The first color filter overlaps the first plurality of adjacent pixel regions, the second color filter overlaps the second plurality of adjacent pixel regions, the third color filter overlaps the third plurality of adjacent third pixel regions, and each second pattern portion of the plurality of second pattern portions is respectively covered by a color filter from among the first to third color filters.

### BRIEF DESCRIPTION OF DRAWINGS

The above and other features of the inventive concept will become more apparent by describing in detail embodiments thereof with reference to the accompanying drawings, in which:

FIG. 1 is a schematic exploded perspective view of an image sensor according to an embodiment of the inventive concept;

FIGS. 2A to 2C are schematic cross-sectional views of an image sensor according to an embodiment of the inventive concept:

FIG. 3 is a cross-sectional view of an image sensor according to an embodiment of the inventive concept;

FIGS. 4 to 5 are cross-sectional views of an image sensor according to an embodiment of the inventive concept;

FIGS. 6 to 8 are schematic cross-sectional views of an image sensor according to embodiments of the inventive concept;

FIGS. 9A to 9D are schematic plan views of an image sensor according to embodiments of the inventive concept;

FIG. 10A is a schematic view of an image sensor according to an embodiment of the inventive concept;

FIG. 10B is a schematic view of an image sensor according to an embodiment of the inventive concept; and

FIGS. 11 to 13 are schematic cross-sectional views that illustrate a method of forming an image sensor according to an embodiment of the inventive concept.

### DETAILED DESCRIPTION

Embodiments of the inventive concept will be described more fully hereinafter with reference to the accompanying drawings. Like reference numerals may refer to like elements throughout the accompanying drawings.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer, or section. Thus, a first element, component, region, layer, or section discussed below could be termed a second element, component, region, layer, or section without departing from the teachings of the embodiments.

As used herein, the singular forms “a,” “an” and “the” are intended to include the plural forms as well, unless the context clearly indicates otherwise.

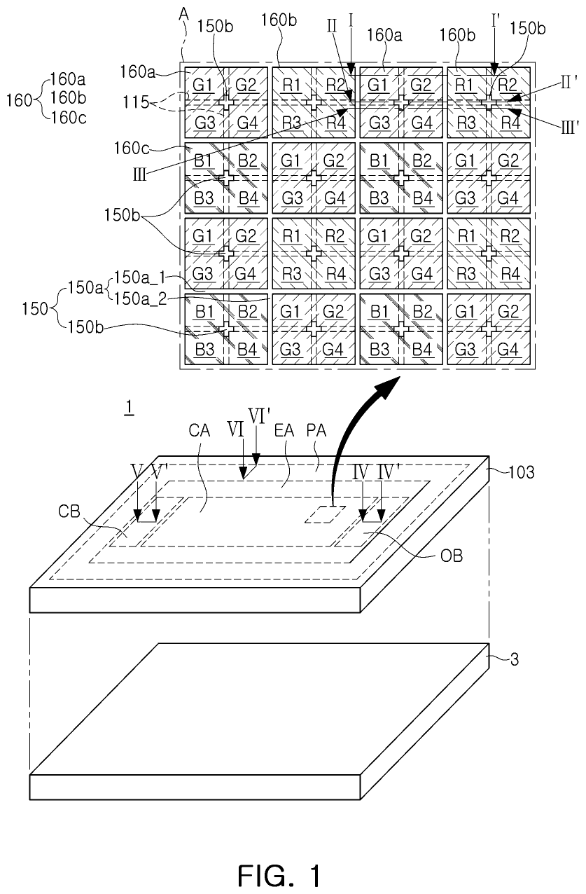

FIG. 1 is a schematic exploded perspective view of an image sensor according to an embodiment of the inventive concept.

Referring to FIG. 1, an image sensor 1 may include a first chip structure 3 and a second chip structure 103 on the first chip structure 3. The first chip structure 3 may be a logic chip, and the second chip structure 103 may be an image sensor chip that includes a plurality of pixel regions G1 to G4, R1 to R4, and B1 to B4, as shown by region A of FIG. 1. In an embodiment, the first chip structure 3 may be a chip stack structure that includes a logic chip and a memory chip.

The second chip structure 103 of the image sensor 1 may include a first region CA, a second region EA, and a third region PA.

The third region PA may be disposed on at least one side of a central region that includes the first region CA and the second region EA. For example, the third region PA may be disposed on both sides of a central region that includes the first region CA and the second region EA, or may surround the central area. The second region EA may be disposed on at least one side of the first region CA. For example, the second region EA may be disposed on either side of the first region CA, may be disposed on both sides of the first region CA, or may surround the first region CA.

The first region CA may include an active pixel sensor array area, the second region EA may include an optical black region OB and an inter-chip connection region CB, and the third region PA may include a pad region in which input/output pads are disposed. The third region PA may be referred to as a pad region.

The first region CA may be an active pixel sensor array region to which light may be incident, the optical black region OB of the second region EA may be a region to which light might not be incident, and the inter-chip connection region CB of the second region EA may be a region electrically connecting an interconnection structure of the first chip structure 3 and an interconnection structure of the second chip structure 103. In an embodiment, the optical black region OB and the inter-chip connection region CB may be arranged in various shapes.

The second chip structure 103 may include a plurality of color filters 160. The plurality of color filters 160 may include first color filters 160a corresponding to a first color, second color filters 160b corresponding to a second color that is different from the first color, and third color filters 160c corresponding to a third color that is different from the first and second colors. For example, the first color may be a green color, the second color may be a red color, and the third color may be a blue color.

The first region CA (e.g., an active pixel sensor array area) may include the plurality of pixel regions G1 to G4, R1 to R4, and B1 to B4, as shown by region A of FIG. 1. A first pixel group G1 to G4 may include a G1 pixel region, a G2 pixel region, a G3 pixel region, and a G4 pixel region that may be adjacent to each other, and may be overlapped by a first color filter 160a. A second pixel group R1 to R4 may include an R1 pixel region, an R2 pixel region, an R3 pixel region, and an R4 pixel region that are adjacent to each other, and may be overlapped by a second color filter 160b. A third pixel group B1 to B4 may include a B1 pixel region, a B2 pixel region, a B3 pixel region, and a B4 pixel region that are adjacent to each other, and may be overlapped by a third color filter 160c.

The second chip structure 103 may further include a grid pattern structure 150 disposed between each first pixel group G1 to G4, each second pixel group R1 to R4, and each third pixel group B1 to B4. The grid pattern structure 150 may include a first pattern portion 150a and a plurality of second pattern portions 150b. The plurality of second pattern portions 150b may be spaced apart from the first pattern portion 150a.

The first pattern portion 150a may include first sub-portions 150a_1 extending parallel to each other in a first direction, and second sub-portions 150a_2 extending parallel to each other in a second direction that is perpendicular to the first direction and intersecting the first sub-portions 150a_1. For example, the first pattern portion 150a may be arranged in a grid shape in which the first sub-portions 150a_1 and the plurality of second sub-portions 150a_2 intersect at right angles.

The first pattern portion 150a may be disposed between proximate pairs of color filters among the plurality of color filters 160. Accordingly, each of the first sub-portions 150a_1 and the second sub-portions 150a_2 may be disposed between proximate pairs of color filters among the plurality of color filters 160.

Each second pattern portion of the plurality of second pattern portions 150b may be respectively overlapped by one a color filter of the plurality of color filters 160 and may be spaced apart from the first sub-portions 150a_1 and the second sub-portions 150a_2 of the first pattern portion 150a.

Each second pattern portion of the plurality of second pattern portions 150b may be respectively overlapped by a color filter from among the first to third color filters 160a, 160b, and 160c. For example, a second pattern portion of the plurality of second pattern portions 150b may be disposed between each pixel region of the first pixel group G1 to G4 that is covered by a first color filter 160a. For example, a second pattern portion of the plurality of second pattern portions 150b may be adjacent to each pixel region of the first pixel group G1 to G4.

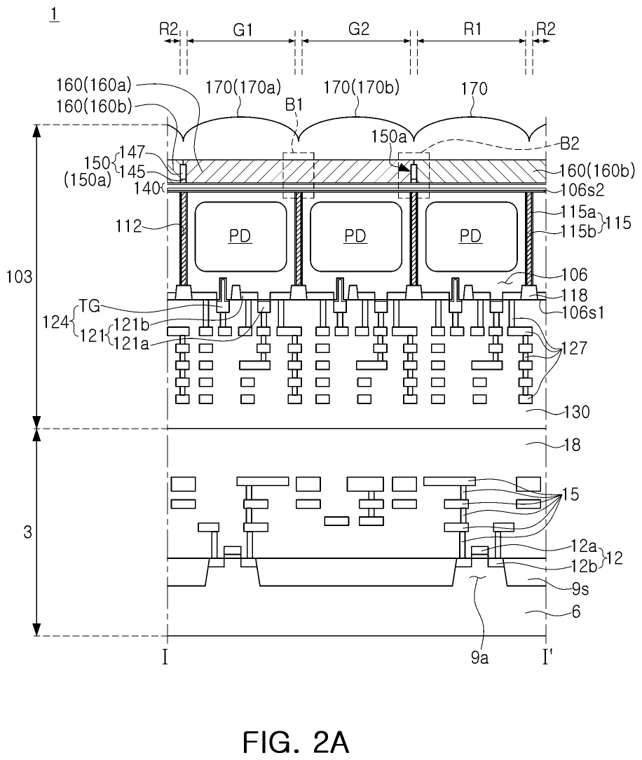

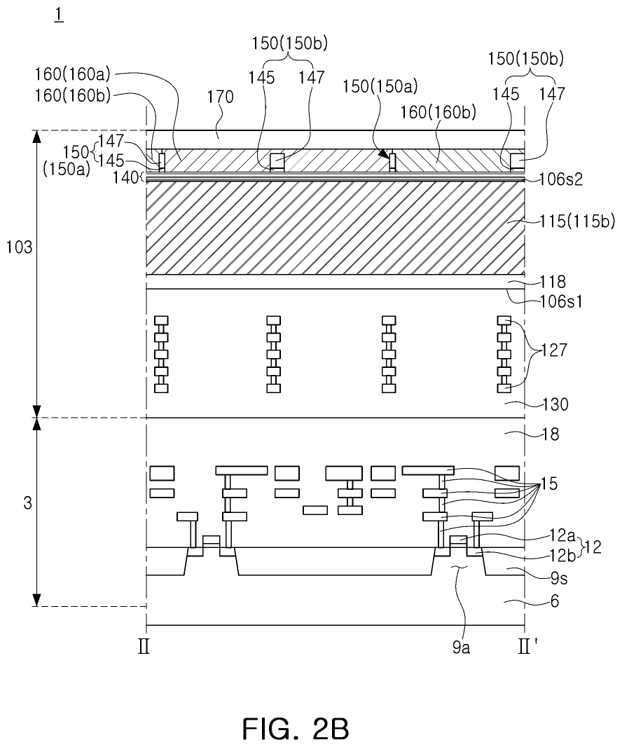

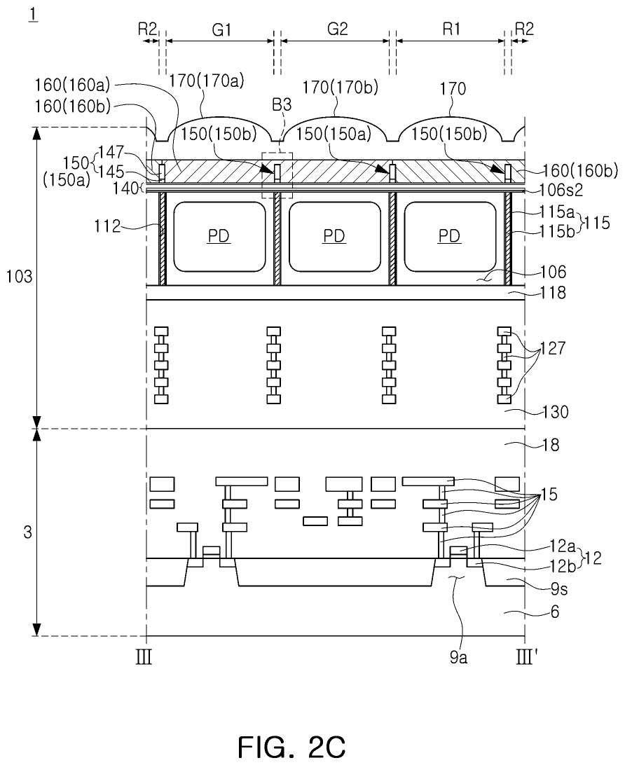

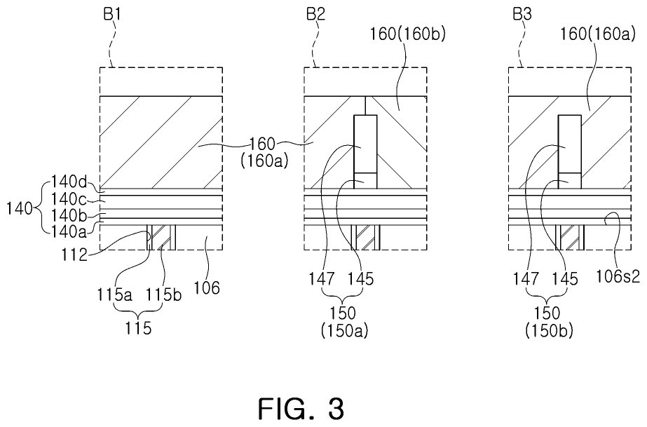

FIG. 2A is a cross-sectional view of the image sensor 1 taken along line I-I′ of FIG. 1, FIG. 2B is a cross-sectional view of the image sensor 1 taken along line II-II′ of FIG. 1, and FIG. 2C is a cross-sectional view of the image sensor 1 taken along line III-III′ of FIG. 1. FIG. 3 is a partially enlarged view of regions B1 and B2 of FIG. 2A and a region B3 of FIG. 2C.

Referring to FIGS. 2A, 2B, 2C, and 3 together with FIG. 1, the first chip structure 3 of the image sensor 1 may include a first substrate 6, a device isolation layer 9s defining an active region 9a on the first substrate 6, a first circuit device 12, a first interconnection structure 15 disposed on the first substrate 6, and a first insulating layer 18 covering the first circuit device 12 and the first interconnection structure 15. The first substrate 6 may be a semiconductor substrate. For example, the first substrate 6 may be a substrate that is formed of a semiconductor material such as a single-crystal silicon substrate. The first circuit device 12 may include a device such as a transistor that includes a first gate 12a and a first source/drain 12b.

In the second chip structure 103 of the image sensor 1, the plurality of pixel regions G1 to G4, R1 to R4, and B1 to B4 may include photoelectric conversion devices PD. For example, each pixel region of the plurality of pixel regions G1 to G4, R1 to R4, and B1 to B4 may include a photoelectric conversion device PD. The photoelectric conversion devices PD may generate and accumulate electric charges corresponding to incident light. For example, each of the photoelectric conversion devices PD may include a photodiode, a phototransistor, a photogate, a pinned photodiode (PPD), or combinations thereof.

The second chip structure 103 may include a second substrate 106 that includes a first surface 106s1 and a second surface 106s2 facing each other, a device isolation layer 118 disposed on the first surface 106s1 of the second substrate 106 and defining an active region, a second circuit device 124 and a second interconnection structure 127 disposed between the first surface 106s1 of the second substrate 106 and the first chip structure 3, and a second insulating layer 130 covering the second circuit device 124 and the second interconnection structure 127. The first surface 106s1 of the second substrate 106 may face the first chip structure 3.

The photoelectric conversion devices PD may be formed in the second substrate 106 and may be spaced apart from each other. The second substrate 106 may be a semiconductor substrate. For example, the second substrate 106 may be a substrate that is formed of a semiconductor material such as a single-crystal silicon substrate.

The second chip structure 103 may include a separation structure 115. The separation structure 115 may at least partially surround each of the photoelectric conversion devices PD. The separation structure 115 may be disposed in a through-opening 112 penetrating through the second substrate 106. The separation structure 115 may penetrate through the second substrate 106. The through-opening 112 may be connected to the device isolation layer 118. Accordingly, the separation structure 115 may be formed of an insulating material such as silicon oxide or the like. The separation structure 115 may include a separation pattern 115b and a separation insulating layer 115a covering a side surface of the separation pattern 115b. For example, the separation insulating layer 115a may include a silicon oxide, and the separation pattern 115b may include polysilicon.

In an embodiment, the separation structure 115 may be disposed in a grid shape. For example, the separation structure 115 may be disposed as a grid shape beneath the grid pattern structure 150, as shown by the dashed lines of region A of FIG. 1.

The second circuit device 124 may include a transfer gate TG and active devices 121. An active device of the active devices 121 may be a transistor that includes a second gate 121a and a second source/drain 121b. The transfer gate TG may transmit charges from an adjacent photoelectric conversion device PD to an adjacent floating diffusion region, and an active device of the active devices 121 may be at least one of a source follower transistor, a reset transistor, and a select transistor. The transfer gate TG may be a vertical transfer gate that includes a portion penetrating the first surface 106s1 of the second substrate 106.

A wiring structure may include multilayer interconnection lines disposed on different height levels in a third direction which is perpendicular to the first and second directions, and vias electrically connecting the multilayer interconnection lines to each other and electrically connecting the multilayer interconnection lines to the second circuit device 124.

The first insulating layer 18 and the second insulating layer 130 may be bonded to each other and may contact each other. Each of the first and second insulating layers 18 and 130 may be formed to have a multilayer structure that includes various types of insulating layers. For example, the second insulating layer 130 may be formed to have a multilayer structure that includes at least two layers selected from among a silicon oxide layer, a low-k dielectric layer, or a silicon nitride layer.

The second chip structure 103 may include an insulating structure 140 disposed on the second surface 106s2 of the second substrate 106. The insulating structure 140 may cover the separation structure 115.

As illustrated in FIG. 3, the insulating structure 140 may include a plurality of sequentially stacked layers. The plurality of sequentially stacked layers may include an anti-reflection layer that adjusts a refractive index of incident light such that the incident light travels to the photoelectric conversion devices PD at high transmissivity. For example, the plurality of sequentially stacked layers may include at least two layers selected from among an aluminum oxide layer, a hafnium oxide layer, a silicon oxynitride layer, a silicon oxide layer, or a silicon nitride layer. For example, the insulating structure 140 may include a first layer 140a, a second layer 140b, a third layer 140c, and a fourth layer 140d sequentially stacked on each other. For example, the first layer 140a may be an aluminum oxide layer, each of the second and fourth layers 140b and 140d may be a hafnium oxide layer, and the third layer 140c may be a silicon oxide layer.

In an embodiment, a thickness in the third direction of the first layer 140a may be substantially the same as a thickness in the third direction of the fourth layer 140d.

In an embodiment, a thickness in the third direction of the second layer 140b may be greater than the thickness in the third direction of each of the first and fourth layers 140a and 140d. For example, the thickness in the third direction of the second layer 140b may range from about five times to about seven times the thickness in the third direction of the first layer 140a.

In an embodiment, a thickness in the third direction of the third layer 140c may be greater than the thickness in the third direction of the second layer 140b. For example, the thickness in the third direction of the third layer 140c may range from about six times to about eight times the thickness in the third direction of the first layer 140a.

As described with reference to FIG. 1, the second chip structure 103 may include the grid pattern structure 150 that includes the first pattern portion 150a and the plurality of second pattern portions 150b spaced apart from the first pattern portion 150a. The grid pattern structure 150 may be disposed on the insulating structure 140.

Each of the first pattern portion 150a and each second pattern portion of the plurality of second pattern portions 150b may include a first material pattern 145 and a second material pattern 147 disposed on the first material pattern 145. The first material pattern 145 may contact the insulating structure 140. A thickness in the third direction of the second material pattern 147 may be greater than a thickness in the third direction of the first material pattern 145.

The first material pattern 145 may include a first material, and the second material pattern 147 may include a second material that is different from the first material.

In an embodiment, the first material of the first material pattern 145 may include a conductive material. For example, the first material pattern 145 may be formed of a conductive material that includes at least one of a metal or a metal nitride. For example, the first material pattern 145 may include at least one of titanium (Ti), tantalum (Ta), titanium nitride (TiN), tantalum nitride (TaN), or tungsten (W).

In an embodiment, the second material of the second material pattern 147 may include an insulating material. The second material of the second material pattern 147 may be a low refractive index (LRI) material. For example, the second material of the second material pattern 147 may have a refractive index within the range of about 1.1 to about 1.8. The second material pattern 147 may include an oxide or a nitride that includes silicon (Si), aluminum (Al), or a combination thereof. For example, the second material pattern 147 may include a silicon oxide arranged in a porous structure or silica nanoparticles arranged in a mesh structure.

As described with reference to FIG. 1, the second chip structure 103 may include the plurality of color filters 160, that includes the first to third color filters 160a, 160b, and 160c. The plurality of color filters 160 may be disposed on the insulating structure 140. The plurality of color filters 160 may transmit light of specific wavelengths therethrough such that the light may reach the photoelectric conversion devices PD. For example, the plurality of color filters 160 may be formed of a mixture of a resin and a pigment that includes a metal or a metal oxide. A thickness in the third direction of each color filter of the plurality of color filters 160 may be greater than a thickness in the third direction of the grid pattern structure 150. The plurality of color filters 160 may cover the grid pattern structure 150 on the insulating structure 140. The plurality of color filters 160 may cover side surfaces and upper surfaces of the grid pattern structure 150 on the insulating structure 140. An upper surface of each color filter of the plurality of color filters 160 may be disposed on a higher level in the third direction than an upper surface of the grid pattern structure 150.

In the grid pattern structure 150, the first pattern portion 150a may be disposed between proximate pairs of color filters among the plurality of color filters 160.

The first pattern portion 150a may include first and second side surfaces opposing each other, and the first and second side surfaces of the first pattern portion 150a may respectively contact or be adjacent to color filters of the plurality of color filters 160 that correspond to different colors. For example, a portion of the first pattern portion 150a may include a first side surface contacting a first color filter 160a and a second side surface contacting a second color filter 160b. In an embodiment, an upper surface of a portion of the first pattern portion 150a may contact two of a first to third color filter 160a, 160b, and 160c, for example, a first color filter 160a and a second color filter 160b.

In each second pattern portion of the plurality of second pattern portions 150b, an entire side surface may contact or be adjacent to one of a first to third color filter 160a, 160b, and 160c. For example, the entire side surface of a second pattern portion of the plurality of second pattern portions 150b may contact a first color filter 160a. As an example, an entire side surface and an entire upper surface of a second pattern portion of the plurality of second pattern portions 150b may contact a first color filter 160a. One of a first to third color filter 160a, 160b, and 160c may cover the entire upper surface and the entire side surface of a second pattern portion of the plurality of second pattern portions 150b.

The second chip structure 103 may include a plurality of microlenses 170 disposed on the plurality of color filters 160. The plurality of microlenses 170 may include a first plurality of microlenses 170 disposed on a first color filter 160a, a second plurality of microlenses 170 disposed on a second color filter 160b, and a third plurality of microlenses disposed on a third color filter 160c. Each microlens of the plurality of microlenses 170 may respectively overlap a photoelectric conversion device PD. Each microlens of the plurality of microlenses 170 may arranged in a convex shape which curves in a direction away from the first chip structure 3. The plurality of microlenses 170 may condense incident light into the photoelectric conversion devices PD. The plurality of microlenses 170 may be formed of a transparent photoresist material or a transparent thermosetting resin material. For example, the plurality of microlenses 170 may be formed of a TMR-based resin, such as a TMR-based resin which is manufactured by Tokyo Ohka Kogo, Co., or an MFR-based resin, such as an MFR-based resin which is manufactured by Japan Synthetic Rubber Corporation, but the plurality of microlenses 170 may alternatively, or additionally be formed of other materials.

Each microlens of the plurality of microlenses 170 may be arranged in a convex shape which curves in a direction away from the first chip structure 3 (e.g., a direction away from the second substrate 106). A center of each microlens of the plurality of microlenses 170 might not overlap the plurality of second pattern portions 150b. For example, a first microlens 170a and a second microlens 170b that are adjacent to each other may be disposed on a first color filter 160a, and a second pattern portion of the plurality of second pattern portions 150b which includes an upper surface and an entire side surface that is covered by the first color filter 160a might not be overlapped by the center of the first microlens 170a and the center of the second microlens 170b, and may be overlapped by a boundary region disposed between the first microlens 170a and the second microlens 170b. The center of each microlens of the plurality of microlenses 170 may refer to a most convex portion of each microlens of the plurality of microlenses 170.

According to the above-described embodiments, a color filter among the plurality of color filters 160 (e.g., a first color filter 160a) may overlap a plurality of photoelectric conversion devices PD disposed in a plurality of pixel regions (e.g., pixel regions in a first pixel group G1 to G4) so that the image sensor 1 may be more sensitive to a color (e.g., the first color of the first color filter 160a, i.e., the green color). The plurality of color filters 160 may likewise increase the sensitivity of the image sensor 1 to the second color and the third color.

According to the above-described embodiments, in the grid pattern structure 150, the first pattern portion 150a may include the first material pattern 145, which may be formed of a conductive material and may serve as a charge path for removing charges, and the plurality of second pattern portions 150b, each second pattern portion of which has entire side surfaces and upper surfaces that may be covered by a color filter corresponding to one color, may omit a conductive material, which may reduce sensitivity in pixel regions that are overlapped by the color filter corresponding to the one color. As a result, optical crosstalk may be suppressed, and the sensitivity of the image sensor 1 to the one color may be increased.

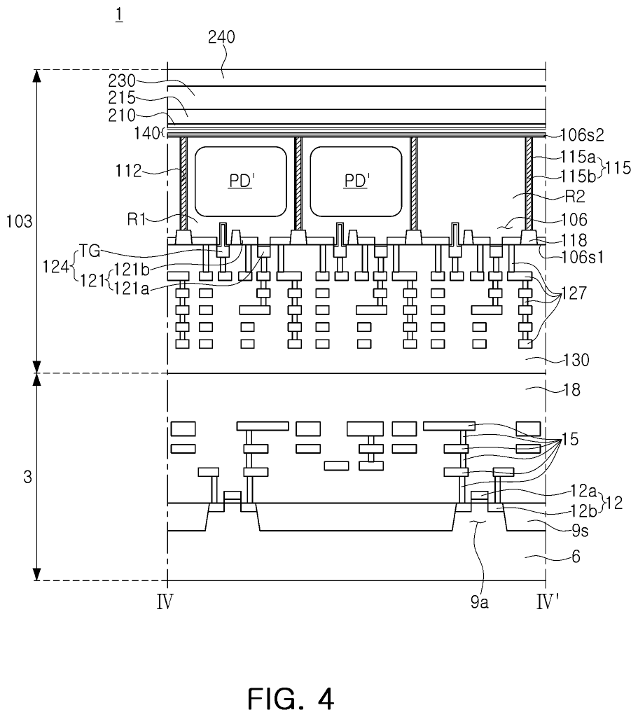

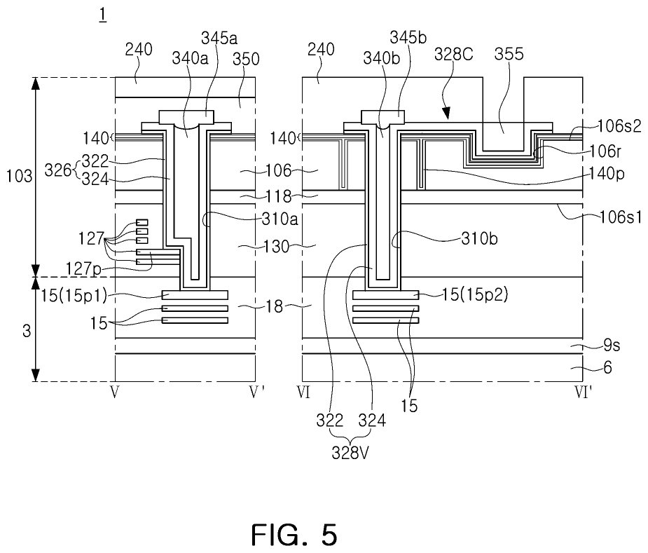

FIG. 4 is a cross-sectional view of the image sensor 1 taken along line IV-IV′ of FIG. 1, and may illustrate the optical black region OB. FIG. 5 is a cross-sectional view of the image sensor 1 taken along line V-V and along line VI-VI′ of FIG. 1, and may illustrate the inter-chip connection region CB and the pad region PA. Hereinafter, repeated descriptions of components that have been described with reference to FIGS. 1 to 3 will be omitted.

Referring to FIG. 4 together with FIGS. 1 to 3, in the optical black region OB of the second chip structure 103, a region in which a photoelectric conversion device PD′ is formed in the same manner as the above-described photoelectric conversion devices PD may be referred to as a first reference region R1, and a region in which a photoelectric conversion device PD is omitted may be referred to as a second reference region R2.

First reference regions R1 and second reference regions R2 may be disposed in the second substrate 106, and may be separated by the separation structure 115. For example, the separation structure 115 may surround side surfaces of each of the first reference regions R1 and the second reference regions R2.

A second reference region R2 may be a comparison region in which a photoelectric conversion device PD is omitted, or a comparison region in which photodiodes of a photoelectric conversion device PD are omitted.

In the optical black region OB of the second region EA of the image sensor 1, the second chip structure 103 may include the insulating structure 140 disposed on the second surface 106s2 of the second substrate 106.

In the optical black region OB of the second region EA of the image sensor 1, the second chip structure 103 may include light-shielding conductive layers 210 and 215, a first light-shielding color filter layer 230, and an upper capping layer 240 sequentially stacked on the insulating structure 140.

The light-shielding conductive layers 210 and 215 and the first light-shielding color filter layer 230 may constitute a light-shielding pattern that may block light. The light-shielding pattern may prevent light from entering a first reference region R1 and a second reference region R2. The light-shielding conductive layers 210 and 215 may include a metal nitride layer that includes a material such as titanium nitride (TiN), tungsten nitride (WN), or the like, and a metal layer that may include a material such as titanium (Ti), tungsten (W), copper (Cu), aluminum (Al), silver (Ag), or the like, and the light-shielding conductive layers 210 and 215 may be sequentially stacked. The first light-shielding color filter layer 230 may include a blue color filter. The upper capping layer 240 may include the same material as the plurality of microlenses 170.

The optical black region OB may remove a noise signal that may be caused by dark current. For example, light may be blocked by the light-shielding conductive layers 210 and 215 and the first light-shielding color filter layer 230, and a first reference region R1 that includes a photoelectric conversion device PD′ may be used as a reference pixel that may remove noise that may be caused by a photodiode of the image sensor 1. In addition, when light is blocked by the light-shielding conductive layers 210 and 215 and the first light-shielding color filter layer 230, a second reference region R2 in which a photodiode is omitted may remove noise that may be caused by other components of the image sensor 1 by checking process noise.

Referring to FIG. 5 together with FIGS. 1 to 4, the image sensor 1 may include a first via hole 310a penetrating through at least a portion of the first chip structure 3 and at least a portion of the second chip structure 103 in the inter-chip connection region CB of the second region EA, and a second via hole 310b penetrating through at least a portion of the first chip structure 3 and at least a portion of the second chip structure 103 in the third region PA.

The first via hole 310a may sequentially penetrate through the insulating structure 140 and the second substrate 106 and may extend in the third direction to sequentially penetrate through the device isolation layer 118 the second insulating layer 130, and a portion of the first insulating layer 18. The second via hole 310b may sequentially penetrate through the insulating structure 140 and the second substrate 106, and may extend in the third direction to sequentially penetrate through the device isolation layer 118, the second insulating layer 130, and a portion of the first insulating layer 18.

The first via hole 310a may expose a first pad 15p1 of the first interconnection structure 15 and a pad portion 127p of the second interconnection structure 127, and the second via hole 310b may expose a second pad 15p2 of the first interconnection structure 15 and may be spaced apart from the second interconnection structure 127.

The first via hole 310a may include a connection conductive layer 326, and the second via hole 310b may include an input/output conductive layer 328V. The connection conductive layer 326 may electrically connect the first and second interconnection structures 15 and 127 to each other.

The connection conductive layer 326 and the input/output conductive layer 328V may each include a first conductive layer 322 and a second conductive layer 324. The first conductive layer 322 may be a barrier layer that includes a material such as titanium nitride (TiN) or the like, and the second conductive layer 324 may be a metal layer that includes a material such as tungsten (W), copper (Cu), aluminum (Al), or the like.

The image sensor 1 may include gap-fill insulating layers 340a and 340b that may respectively fill the first and second via holes 310a and 310b and may be partially surrounded by the connection conductive layer 326 and the input/output conductive layer 328V, respectively. The gap-fill insulating layers 340a and 340b may each include concave upper surfaces. The image sensor 1 may include buffer insulating layers 345a and 345b, which may cover the gap-fill insulating layers 340a and 340b and include upper surfaces disposed on levels higher in the third direction than the upper surface of the insulating structure 140. The buffer insulating layers 345a and 345b may include a cured photoresist material.

The image sensor 1 may further include a second light-shielding color filter layer 350 on the inter-chip connection region CB in the second region EA, and the second light-shielding color filter layer 350 may cover the buffer insulating layer 345a. The second light-shielding color filter layer 350 may extend from the first light-shielding color filter layer 230 in the optical black region OB of the second region EA. The first and second light-shielding color filter layers 230 and 350 may include a same material as each other and may filter a same color as each other. For example, each of the first and second light-shielding color filter layers 230 and 350 may be a blue color filter.

The image sensor 1 may further include an input/output pad 355 in the third region PA. The input/output pad 355 may be disposed on a portion 328C of the input/output conductive layer 328V extending in a direction parallel to the second surface 106s2 of the second substrate 106. At least a portion of the input/output pad 355 may be covered by the second substrate 106. For example, the input/output pad 355 may include an upper surface disposed on a higher level in the third direction than the second surface 106s2 of the second substrate 106, and a lower surface disposed on a lower level in the third direction than the second surface 106s2 of the second substrate 106. The insulating structure 140 may be disposed on the second surface 106s2 of the second substrate 106, and the portion 328C of the input/output conductive layer 328V may be disposed on the insulating structure 140. The upper capping layer 240 of the optical black region OB of the second region EA may extend in the third direction above the inter-chip connection region CB and the third region PA of the second region EA. The upper capping layer 240 may cover the inter-chip connection region CB of the second region EA, may expose the input/output pad 355 in the third region PA, and may cover the other portions of the third region PA.

The image sensor 1 may further include a separation pattern 140p penetrating through the second substrate 106 in the third region PA. In an embodiment, the separation pattern 140p may extend in the third direction from at least a portion of the insulating structure 140.

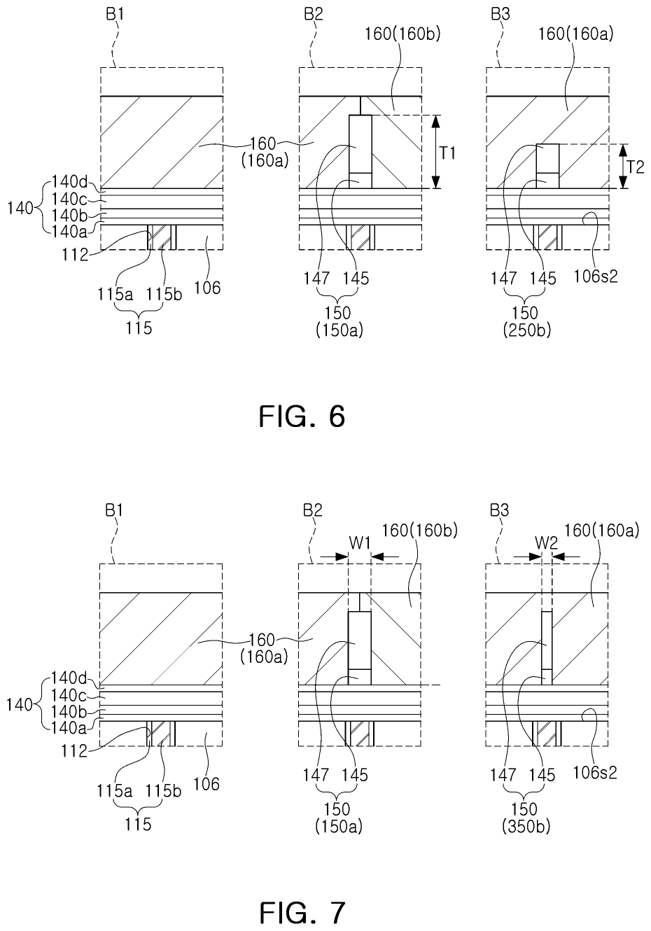

Referring back to FIGS. 1 to 3, in an embodiment, each second pattern portion of the plurality of second pattern portions 150b may be arranged in a cross-like shape in which a first line portion and a second line portion intersect each other. In each of the second pattern portions 150b, the first line portion or the second line portion may have substantially a same width in the first and second directions and a thickness in the third direction as the first pattern portion 150a. However, embodiments of the inventive concept are not necessarily limited thereto. For example, in at least one of second pattern portion of the plurality of second pattern portions 150b, the first line portion or the second line portion may have a width in the first and/or second direction or a thickness in the third direction which is different from the width in the first and/or second direction or the thickness in the third direction of the first pattern portion 150a. Hereinafter, the first pattern portion 150a and the plurality of second pattern portions 150b according to embodiments of the inventive concept will be described with reference to FIGS. 6 to 8.

FIGS. 6 to 8 show various implementations of regions B1, B2, and B3 of FIG. 3 according to embodiments of the inventive concept. Repeated descriptions of like elements will be omitted. Hereinafter, the width of the plurality of second pattern portions 150b may be understood as the width in the first and/or second direction of the first line portions or the second line portions of the plurality of second pattern portions 150b.

In an embodiment, referring to FIG. 6, in the grid pattern structure 150, the first pattern portion 150a may have a first thickness T1 in the third direction and a second pattern portion 250b may have a second thickness T2 in the third direction which is smaller than the first thickness T1.

In an embodiment, the second thickness T2 may be equal to or greater than half the first thickness T1. In an embodiment, the second thickness T2 may be less than half the first thickness T1.

In an embodiment, referring to FIG. 7, in the grid pattern structure 150, the first pattern portion 150a may have a first width W1 in the first and/or second direction, and a second pattern portion 350b may have a second width W2 in the first and/or second direction which is less than the first width W1.

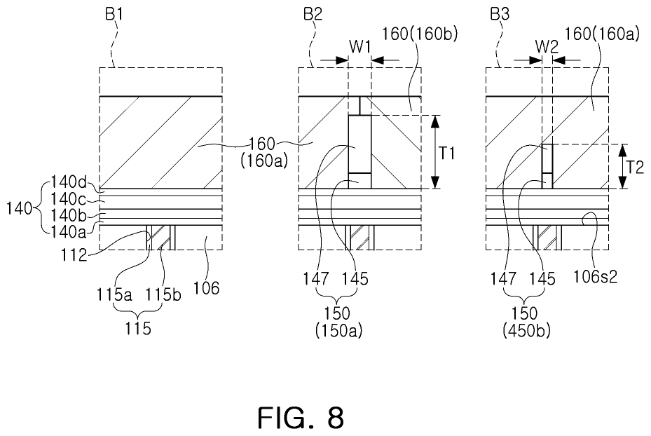

In an embodiment, referring to FIG. 8, in the grid pattern structure 150, the first pattern portion 150a may have a first width W1 in the first and/or second direction and a first thickness T1 in the third direction, and a second pattern portion 450b may have a second width W2 in the first and/or second direction which is less than the first width W1, and a second thickness T2 in the third direction which is less than the first thickness T1.

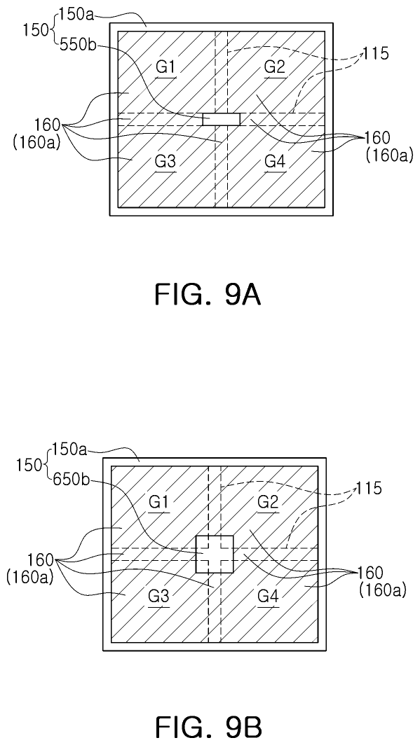

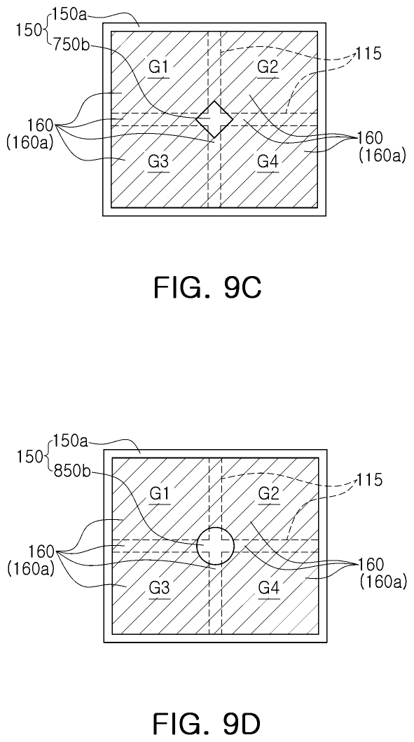

Referring back to FIG. 1, each second pattern portion of the plurality of second pattern portions 150b may be arranged in a cross-like shape in which a first line portion and a second line portion intersect, but embodiments of the inventive concept are not necessarily limited thereto. For example, each second pattern portion of the plurality of second pattern portions 150b may be arranged in various shapes. Hereinafter, a second pattern portion of the plurality of second pattern portions 150b according to embodiments of the inventive concept will be described with reference to FIGS. 9A to 9D.

FIGS. 9A to 9D show implementations of a second pattern portion 550b, 650b, 750b, and 850b, respectively, that is adjacent to the pixel regions of a pixel group (e.g., the first pixel regions of a first pixel group G1 to G4) according to embodiments of the inventive concept. In FIGS. 9A to 9D, the separation structure 115 is represented by dashed lines which indicate that the separation structure 115 may include a portion that is disposed below the first pattern portion 150a.

In an embodiment, referring to FIG. 9A, in the grid pattern structure 150, a second pattern portion 550b may be in the form of a bar or a line extending in one direction.

In an embodiment, referring to FIG. 9B, in the grid pattern structure 150, a second pattern portion 650b may be in the form of a rectangle in which a pair of sides of the rectangle are parallel to the first portion of the first pattern portion 150a.

In an embodiment, referring to FIG. 9C, in the grid pattern structure 150, a second pattern portion 750b may be in the form of a rhombus in which a first pair of sides of the rhombus form an angle with the first portions of the first pattern portion 150a and a second pair of sides of the rhombus form an angle with the second portions of the first pattern portion 150a.

In an embodiment, referring to FIG. 9D, in the grid pattern structure 150, a second pattern portion 750b may be in the form of a circle or an ellipse.

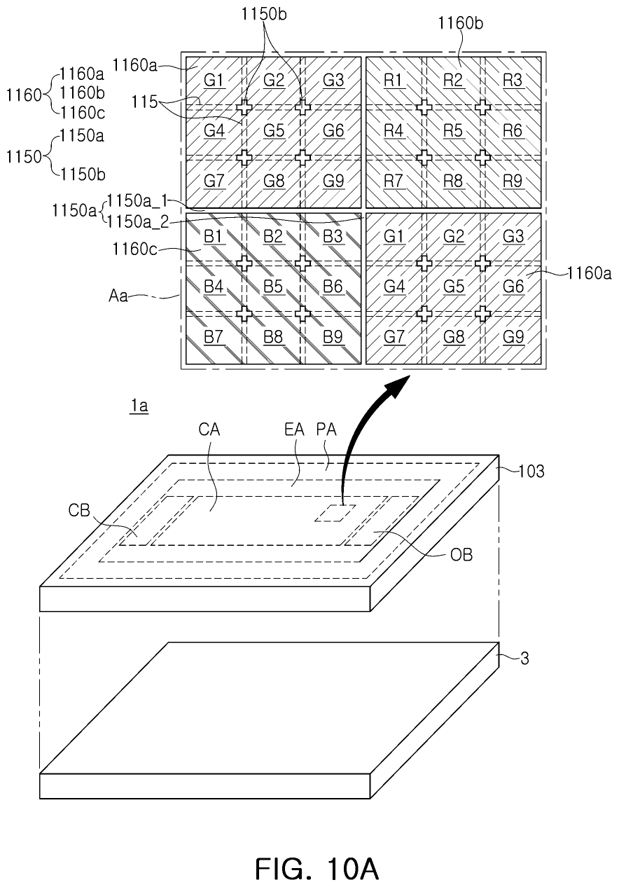

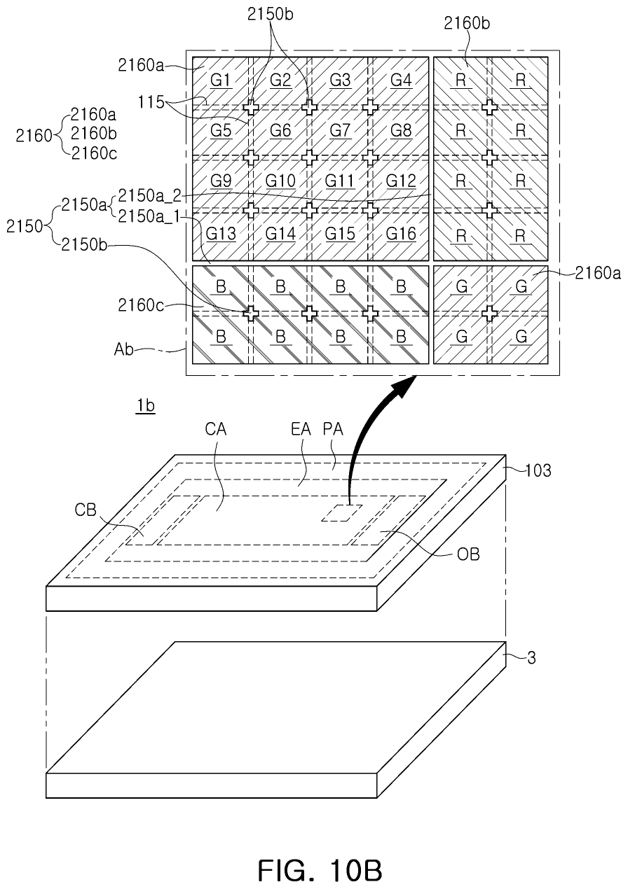

FIGS. 10A and 10B illustrate implementations of the grid pattern structure 150 and the plurality of color filters 160 according to embodiments of the inventive concept.

In an embodiment, referring to FIG. 10A, a plurality of color filters 1160 may include first color filters 1160a corresponding to the first color, second color filters 1160b corresponding to the second color, and third color filters 1160c corresponding to the third color. A first color filter 1160a may overlap nine pixel regions G1 to G9, a second color filter 1160b may overlap nine pixel regions R1 to R9, and a third color filter 1160c may overlap nine pixel regions B1 to B9.

Similarly to the grid pattern structure 150 as described with reference to FIG. 1, a grid pattern structure 1150 may include a first pattern portion 1150a, which may be disposed between proximate pairs of color filters among the plurality of color filters 1160, and a plurality of second pattern portions 1150b. Each second pattern portion of the plurality of second pattern portions 1150b may be respectively overlapped by a color filter from among the plurality of color filters 1160. The first pattern portion 1150a may include first sub-portions 1150a_1 that may extend parallel to each other in the first direction, and second sub-portions 1150a_2, that may extend parallel to each other in the second direction and perpendicularly intersect the first sub-portions 1150a_1. The plurality of second pattern portions 1150b may be spaced apart from the first pattern portion 1150a.

A group of second pattern portions from among the plurality of second pattern portions 1150b may be disposed between an adjacent pair of first sub-portions 1150a_1 and between an adjacent pair of second sub-portions 1150a_2.

Each second pattern portion of the plurality of second pattern portions 1150b may be disposed between four adjacent pixel regions and may not overlap the first pattern portion 1150a.

As shown by FIG. 10A, in an embodiment, a second pattern portion of the plurality of second pattern portions 1150b may be arranged in a cross-like shape. However, the shape of the second pattern portion may alternatively be a bar or line shape, a rectangular shape, a rhombus shape, or a circular or elliptical shape, as described with reference to FIGS. 9A to 9DT.

In an embodiment, referring to FIG. 10B, a plurality of color filters 2160 may include first color filters 2160a corresponding to the first color, second color filters 2160b corresponding to the second color, and third color filters 2160c corresponding to the third color. Among the first to third color filters 2160a, 2160b, and 2160c, one color filter (e.g., a first color filter 2160a) may overlap sixteen pixel regions (e.g., first pixel regions G1 to G16). For example, FIG. 10B illustrates one complete color filter 2160a, and three partial color filters 2160a, 2160b, and 2160c, each of which correspond to sixteen pixel regions. Similarly to the grid pattern structure 1150 as described with reference to FIG. 10A, a grid pattern structure 2150 may include a first pattern portion 2150a, which may be disposed between proximate pairs of color filters among the plurality of color filters 2160, and a plurality of second pattern portions 2150b. Each second pattern portion of the plurality of second pattern portions 2150b may be respectively overlapped by a color filter from among the plurality of color filters 2160. The first pattern portion 2150a may include first sub-portions 2150a_1 that extend parallel to each other in the first direction, and second sub-portions 2150a_2 that extend parallel to each other in the second direction and perpendicularly intersect the first sub-portions 2150a_1. The plurality of second pattern portions 2150b may be spaced apart from the first pattern portion 2150a.

A group of second pattern portions from among the plurality of second pattern portions 2150b may be disposed between an adjacent pair of first sub-portions 2150a_1 and between an adjacent pair of second sub-portions 2150a_2.

Each second pattern portion of the plurality of second pattern portions 2150b may be disposed between four adjacent pixel regions and may not overlap the first pattern portion 2150a.

As described with reference to FIG. 1, in an embodiment, a color filter may overlap four pixel regions. As described with reference to FIG. 10A, in an embodiment, a color filter may overlap nine pixel regions. As described with reference to FIG. 10B, in an embodiment, a color filter may overlap sixteen pixel regions. However, embodiments of the inventive concept are not necessarily limited thereto. For example, a color filter may overlap sixteen or more pixel regions.

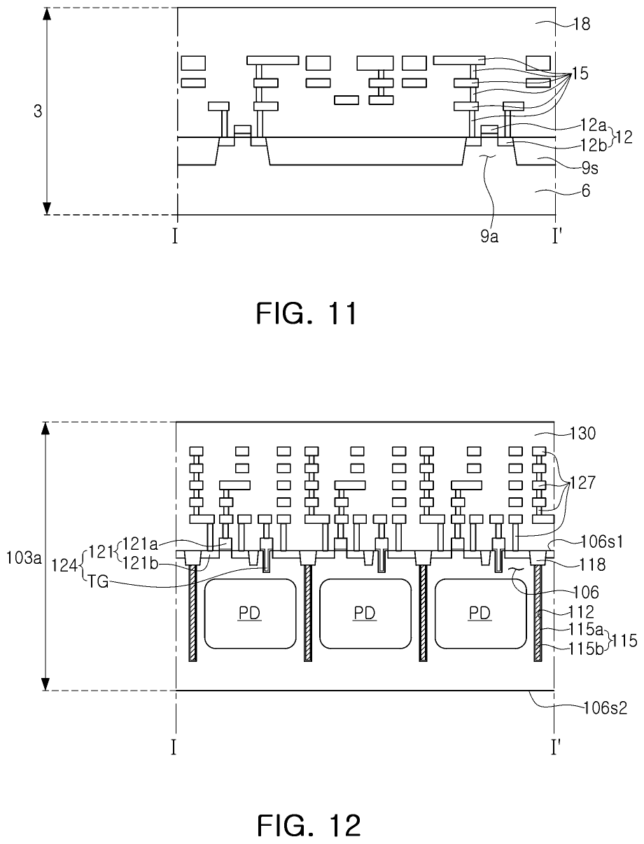

FIGS. 11 to 13 are schematic cross-sectional views of the image sensor 1 taken along line I-I′ of FIG. 1 illustrating a method of forming an image sensor according to an embodiment of the inventive concept.

Referring to FIG. 11, a first chip structure 3 may be formed. The forming of the first chip structure 3 may include preparing a first substrate 6, defining an active region 9a on the first substrate 6 by forming a device isolation layer 9s, forming a first circuit device 12 on the first substrate 6, forming a first interconnection structure 15 and electrically connecting the first interconnection structure 15 to the first circuit device 12, and covering the first circuit device 12 and the first interconnection structure 15 by forming a first insulating layer 18.

Referring to FIG. 12, a second chip 103a may be formed. Forming the second chip 103a may include preparing a second substrate 106 that includes a first surface 106s1 and a second surface 106s2 opposing each other, forming a separation structure 115 and photoelectric conversion devices PD in the second substrate 106, defining an active region on the first surface 106s1 of the second substrate 106 by forming a device isolation layer 118, forming a second circuit device 124 on the first surface 106s1 of the second substrate 106, forming a second interconnection structure on the first surface 106s1 of the second substrate 106, and covering the second circuit device 124 and the second interconnection structure 127 by forming a second insulating layer 130. The order of forming the separation structure 115, the photoelectric conversion devices PD, and the device isolation layer 118 may vary.

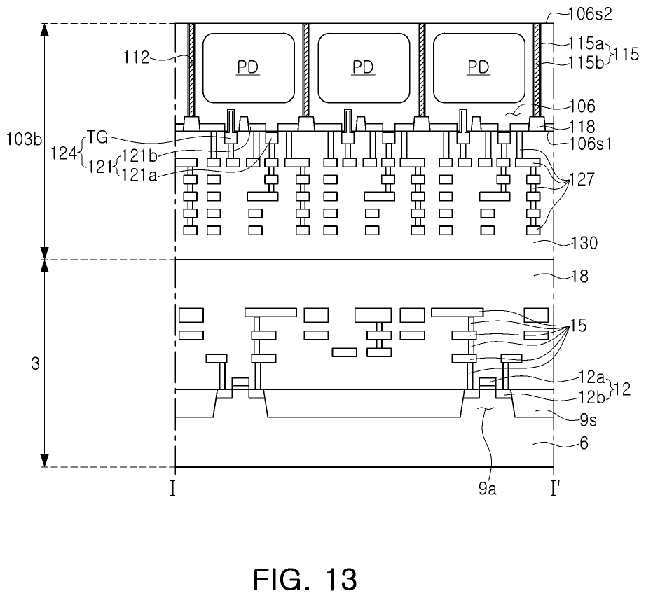

Referring to FIG. 13, the first chip structure 3 may be bonded with the second chip (103a in FIG. 12) through a wafer bonding process. The wafer bonding process may include bonding the first insulating layer 18 of the first chip structure 3 and the second insulating layer 130 of the second chip 103a to each other. A thickness in the third direction of the second substrate 106 of the second chip (103a of FIG. 12) may be decreased and the separation structure 115 in the second substrate 106 may be exposed by a grinding process. Accordingly, a second chip 103b with a decreased thickness may be formed on the first chip structure 3.

Referring back to FIGS. 1 to 3, an insulating structure 140 may be formed on the second surface 106s2 of the second substrate 106. A grid pattern structure 150, color filters 160, and microlenses 170 may be sequentially formed on the insulating structure 140.

As described above, according to an embodiment of the inventive concept, a color filter may overlap a plurality of photoelectric conversion devices of a plurality of pixel regions. Thus, sensitivity of an image sensor to a color corresponding to the color filter may be increased.

According to an embodiment, a grid pattern structure may include a first pattern portion which is disposed between proximate pairs of color filters, and may include second pattern portions, each of which may include an entire side surface and an entire upper surface that is covered by a color filter corresponding to a color. Such a grid pattern structure and such color filters may be provided to increase the sensitivity of an image sensor to the color and to suppress optical crosstalk. Thus, resolution of the image sensor may be increased.

While the inventive concept has been particularly shown and described with reference to embodiments thereof, it will be understood by one of ordinary skill in the art that variations in form and detail may be made therein without departing from the scope of the present disclosure.

What is claimed is:

1. An image sensor comprising:
a first chip structure that includes a first substrate, a first circuit device and a first interconnection structure disposed on the first substrate, and a first insulating layer covering the first circuit device and the first interconnection structure; and
a second chip structure disposed on the first chip structure,
wherein the second chip structure comprises:
a second substrate that includes a first surface facing the first chip structure and a second surface opposing the first surface;
a second circuit device and a second interconnection structure disposed between the first surface of the second substrate and the first chip structure;
a second insulating layer covering the second circuit device and the second interconnection structure;
photoelectric conversion devices disposed in the second substrate;
an insulating structure disposed on the second surface of the second substrate;
a grid pattern structure disposed on the insulating structure;
a plurality of color filters disposed on the insulating structure and the grid pattern structure; and
a plurality of microlenses disposed on the plurality of color filters,
wherein the grid pattern structure includes a first pattern portion arranged in a grid shape and a plurality of second pattern portions spaced apart from the first pattern portion, and
wherein an upper surface of each color filter of the plurality of color filters is disposed on a higher level than an upper surface of the grid pattern structure.

2. The image sensor of claim 1, wherein an entire side surface of each second pattern portion of the plurality of second pattern portions is respectively surrounded by a color filter from among the plurality of color filters.

3. The image sensor of claim 1, wherein the plurality of color filters covers an upper surface of the grid pattern structure.

4. The image sensor of claim 1, wherein:
the plurality of color filters includes a first color filter corresponding to a first color, a second color filter corresponding to a second color that is different from the first color, and a third color filter corresponding to a third color that is different from the first and second colors;
the first pattern portion is disposed between proximate pairs of color filters among the plurality of color filters;
the first pattern portion includes a first side surface and a second side surface opposing each other;
the first and second side surfaces of the first pattern portion respectively contact or are adjacent to two color filters of the plurality of color filters corresponding to different colors; and
an entire side surface of each second pattern portion of the plurality of second pattern portions is respectively surrounded by a color filter from among the plurality of color filters.

5. The image sensor of claim 4, wherein an entire upper surface of each second pattern portion of the plurality of second pattern portions is respectively covered by the color filter that surrounds the entire side surface of the second pattern portion.

6. The image sensor of claim 4, wherein:
the plurality of microlenses includes a first plurality of microlenses disposed on the first color filter, a second plurality of microlenses disposed on the second color filter, and a third plurality of microlenses disposed on the third color filter;
each microlens of the plurality of microlenses is arranged in a convex shape that curves away from the first chip structure; and
a center of each microlens of the plurality of microlenses does not overlap the plurality of second pattern portions.

7. The image sensor of claim 1, wherein:
the grid pattern structure includes a first material pattern and a second material pattern disposed on the first material pattern;
the second material pattern includes a material that is different from a material included in the first material pattern; and
the first material pattern includes a conductive material.

8. The image sensor of claim 1, wherein the first pattern portion includes first sub-portions extending parallel to each other in a first direction, and second sub-portions extending parallel to each other in a second direction that is perpendicular to the first direction and intersecting the first sub-portions, and
wherein the plurality of second pattern portions are spaced apart from the first sub-portions and the second sub-portions.

9. The image sensor of claim 8, wherein one second pattern portion from among the plurality of second pattern portions is disposed between a proximate pair of the first sub-portions and between a proximate pair of the second sub-portions, wherein the proximate pair of second sub-portions intersect the proximate pair of first sub-portions.

10. The image sensor of claim 8, wherein more than one second pattern portion from among the plurality of second pattern portions is disposed between a proximate pair of first sub-portions and between a proximate pair of second sub-portions, wherein the proximate pair of second sub-portions intersect the proximate pair of first sub-portions.

11. The image sensor of claim 1, wherein a thickness of the first pattern portion is greater than a thickness of each second pattern portion of the plurality of second pattern portions.

12. The image sensor of claim 1, wherein a width of the first pattern portion is greater than a width of each second pattern portion of the plurality of second pattern portions.

13. The image sensor of claim 12, wherein a thickness of the first pattern portion is greater than a thickness of each second pattern portion of the plurality of second pattern portions.

14. The image sensor of claim 1, wherein:
the insulating structure includes a first layer, a second layer, a third layer, and a fourth layer, wherein the first layer, the second layer, the third layer, and the fourth layer are sequentially stacked;
the first layer is an aluminum oxide layer, each of the second and fourth layers is a hafnium oxide layer, and the third layer is a silicon oxide layer;
a thickness of the second layer is greater than a thickness of each of the first and fourth layers; and
a thickness of the third layer is greater than the thickness of the second layer.

15. The image sensor of claim 1, wherein the second chip structure further includes a transfer gate, and
wherein the transfer gate includes a portion extending from the first surface of the second substrate toward the second surface of the second substrate.

16. The image sensor of claim 1, wherein the second chip structure comprises:
a first reference region and a second reference region disposed in the second substrate;
a separation structure disposed in the second substrate;
a light-shielding pattern disposed on the insulating structure and overlapping the first reference region and the second reference region;
a first via hole penetrating through the insulating structure, the second substrate, the second insulating layer, and a portion of the first insulating layer, and exposing a pad portion of the second interconnection structure and a first pad of the first interconnection structure;
a second via hole penetrating through the insulating structure, the second substrate, the second insulating layer, and a portion of the first insulating layer, spaced apart from the second interconnection structure, and exposing a second pad of the first interconnection structure;
a connection conductive layer disposed in the first via hole and electrically connected to the pad portion of the second interconnection structure and the first pad of the first interconnection structure; and
an input/output conductive layer disposed in the second via hole and electrically connected to the second pad of the first interconnection structure,
wherein the photoelectric conversion devices are spaced apart from each other by the separation structures,
wherein the first reference region and each of the photoelectric conversion devices includes a photodiode,
wherein the second reference region does not include a photodiode, and
wherein the light-shielding pattern includes a conductive material layer and a blue color filter layer disposed on the conductive material layer.

17. An image sensor comprising:
a substrate that includes a plurality of photoelectric conversion devices;
an insulating structure disposed on the substrate;
a grid pattern structure disposed on the insulating structure;
a plurality of color filters disposed on the insulating structure; and
a plurality of microlenses disposed on the plurality of color filters,
wherein the grid pattern structure includes a first pattern portion and a plurality of second pattern portions spaced apart from the first pattern portion,
wherein the plurality of color filters includes a first color filter corresponding to a first color, a second color filter corresponding to a second color that is different from the first color, and a third color filter corresponding to a third color that is different from the first and second colors,
wherein the first pattern portion is disposed between proximate pairs of color filters among the plurality of color filters, and
wherein an entire side surface of each second pattern portion of the plurality of second pattern portions is respectively surrounded by a color filter from among the first to third color filters.

18. The image sensor of claim 17, wherein:
an entire upper surface of each second pattern portion of the plurality of second pattern portions is respectively covered by the color filter that surrounds the entire side surface of the second pattern portion;
the plurality of microlenses includes a first plurality of microlenses disposed on the first color filter, a second plurality of microlenses disposed on the second color filter, and a third plurality of microlenses disposed on the third color filter;
each microlens of the plurality of microlenses is arranged in convex shape that curves away from the substrate; and
a center of each microlens of the plurality of microlenses does not overlap the plurality of second pattern portions.

19. An image sensor comprising:
a substrate that includes a first plurality of adjacent pixel regions, a second plurality of adjacent pixel regions, and a third plurality of adjacent pixel regions;
an insulating structure disposed on the substrate;
a grid pattern structure disposed on the insulating structure;
a plurality of color filters disposed on the insulating structure; and
a plurality of microlenses disposed on the plurality of color filters,
wherein the grid pattern structure includes a first pattern portion and a plurality of second pattern portions spaced apart from the first pattern portion,
wherein the plurality of color filters includes a first color filter corresponding to a first color, a second color filter corresponding to a second color that is different from the first color, and a third color filter corresponding to a third color that is different from the first and second colors,
wherein the first pattern portion is disposed between proximate pairs of color filters among the plurality of color filters,
wherein the first color filter overlaps the first plurality of adjacent pixel regions,
wherein the second color filter overlaps the second plurality of adjacent pixel regions,
wherein the third color filter overlaps the third plurality of adjacent third pixel regions, and
wherein each second pattern portion of the plurality of second pattern portions is respectively covered by a color filter from among the first to third color filters.

20. The image sensor of claim 19, wherein:
each pixel region of the first, second, and third pluralities of pixel regions includes a photoelectric conversion device;
the plurality of microlenses includes a first plurality of microlenses disposed on the first color filter, a second plurality of microlenses disposed on the second color filter, and a third plurality of microlenses disposed on the third color filter; and
a center of each microlens of the plurality of microlenses does not overlap the plurality of second pattern portions.
